(19) United States
(12) Patent Application Publication
(10) Pub. No.: US 2023/0328911 A1
(43) Pub. Date: Oct. 12, 2023

(54) INVERTER SYSTEM FOR A DRIVE TRAIN OF A MOTOR VEHICLE

(71) Applicant: VOITH PATENT GMBH, Heidenheim (DE)

(72) Inventors: Gerald Helwich, Eichgraben (AT); Christoph Gruber, Markersdorf (AT)

(21) Appl. No.: 18/042,332

(22) PCT Filed: Aug. 18, 2021
(86) PCT No.: PCT/EP2021/072874

§ 371 Date: Feb. 21, 2023

(30) Foreign Application Priority Data
Aug. 21, 2020 (DE) 10 2020 121 917.2

(51) Int. Cl. H05K 7/14; H05K 7/20; B60L 50/51; H02M 7/00; H05K 9/00

(52) U.S. Cl. CPC H05K 7/14322; H05K 7/20909; B60L 50/51; H02M 7/003; H05K 9/0081

(57) ABSTRACT

An inverter system for a drive train of a motor vehicle is disposed in a multi-part housing. The inverter system includes a control board which can be connected via control cable connections to control lines, DC link capacitors, power semiconductors, control units, and current transformers. The housing is formed with an electronics level, a power level and a connection level. The interior of the housing has a plurality of zones in which different conditions prevail with regard to temperature and/or EMC shielding.

The invention relates to improvements for an inverter system for a drive train of a motor vehicle.

An inverter system or converter device is arranged between a battery and an electric motor so that the energy stored in the battery can be supplied to the motor by the inverter system. The inverter system can comprise individual subunits, such as power converters, power semiconductors, DC-link capacitors, drive units (GDUs) and an open-loop control printed circuit board, which are preferably accommodated in a housing.

In order to be able to ensure the functional reliability of an inverter system, different environmental conditions are required for the individual subunits. In particular, the high amount of waste heat from the power semiconductors requires a cooling structure. Corresponding cooling technologies or cooling structures for inverter systems or converter devices are known from the prior art.

The power converter unit which is described in JP 2015-130735 comprises a housing unit, which is divided into a first housing section and a second housing section. The first housing section accommodates a first power converter and a first cooling device which are integrated in one unit. The second housing section acts as a second cooling device, and a second power converter is arranged in the interior of the second housing section.

DE 10 2017 127 383 A1 discloses a further design for a power converter unit. Two cooling units are arranged in the housing of the power converter unit and are connected via a cooling medium channel. The subunits are arranged, corresponding to their heat development, on one of the cooling faces of the cooling units.

In addition to cooling, there is the problem in an inverter system that, from the point of view of EMC, there may be an influence between the subunits when they are arranged in a housing or the shielding is insufficient. Realizing shielding by means of shielding plates or other additional measures such as shielded cables, shield connections and connections to ground etc. is known from the prior art.

One object of the present invention consists in proposing an inverter system in a housing with which an improved functionality and operational reliability of the inverter system can be achieved.

The object is achieved according to the invention by an embodiment corresponding to independent claim 1. Further advantageous embodiments of the present invention can be gleaned from the dependent claims.

An inverter system for a drive train of a motor vehicle is proposed which is arranged in a multi-part housing, comprising an open-loop control printed circuit board which is connectable to control lines via control cable connections, DC-link capacitors, power semiconductors, drive units (GDUs), power converters and a connection region for DC input and inverter output.

It is proposed according to the invention that the housing comprises, arranged one above the other, an electronics plane, a power plane, and a connection plane, wherein the interior of the housing has a plurality of zones in which different conditions prevail in respect of the temperature and/or the EMC shielding. In accordance with the invention, a zone is understood to mean a region or a room region in which environmental conditions which are specified in a targeted manner are produced. Thus, for example, temperature conditions which have been specified in a targeted manner for a subunit are created or it is ensured that a desired shielding from an EMC point of view takes place.

In this case, the housing can furthermore preferably be separated into a first room and a second room by a separating wall, wherein the power plane and the control plane are arranged in the first room, which in turn is divided into a plurality of zones, and the connection plane is arranged in the second room and forms a zone.

The separation of the rooms is embodied in such a way that in particular no targeted air exchange can take place.

In a preferred embodiment, in the first room the power plane and the control plane arranged therebeneath are separated by a heat sink. In contrast to the separating wall, the heat sink is not configured in such a way that a completely physical separation of the planes takes place, however.

Preferably, the power plane and the control plane each have two zones, wherein, per plane, one zone adjoins a first cooling zone of the heat sink, and, per plane, one zone adjoins a second cooling zone of the heat sink. The heat sink zones each have an upper and a lower side which are each adjoined by one zone.

Thus, in a preferred embodiment, in the power plane the power semiconductors are fastened on the heat sink in the region of the first cooling zone and the DC-link capacitors are fastened on the heat sink in the region of the second cooling zone. In this case, within the meaning of the invention, fastened at the same time means thermally conductively bonded.

Furthermore, preferably the open-loop control printed circuit board is arranged in a depression in the heat sink in the region of the second cooling zone. Owing to the shape of the depression, as well as the material of the heat sink, aluminum, and the selected wall thickness, particularly good EMC shielding is achieved, with the result that further shielding elements can be dispensed with.

The coupling of the power converters and the drive units (GDUs) to the open-loop control printed circuit board takes place by means of connecting cables, wherein the connecting cables run through a zone which is arranged substantially beneath the heat sink. Furthermore, the connecting cables run as long as possible past the heat sink through the power plane to the connection plane, with the result that they are shielded from the entry of any interference (EMC) on the essential length section.

The coupling of the power semiconductors to the DC-link capacitors takes place by means of conductor bars, wherein the conductor bar connection comprises means which enable thermal decoupling of power semiconductors and DC-link capacitors or reduces the entry of heat from the power semiconductors into the DC-link capacitors.

These means can be an electrically insulating thermally conductive element with which thermal energy can be dissipated from the conductor bars onto the housing upper part.

The attached figures show a possible exemplary embodiment in detail. Specifically,

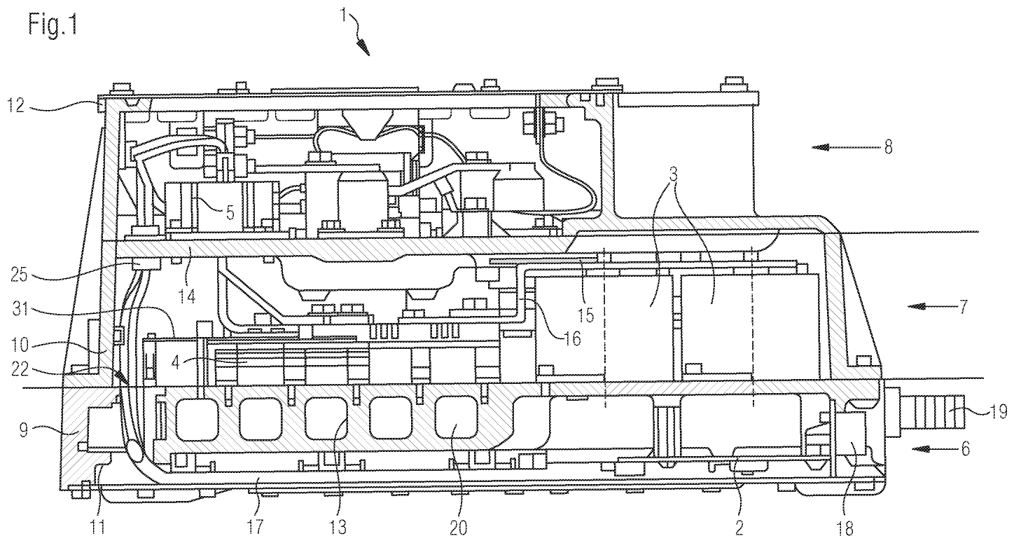

FIG. 1 shows an inverter system in section

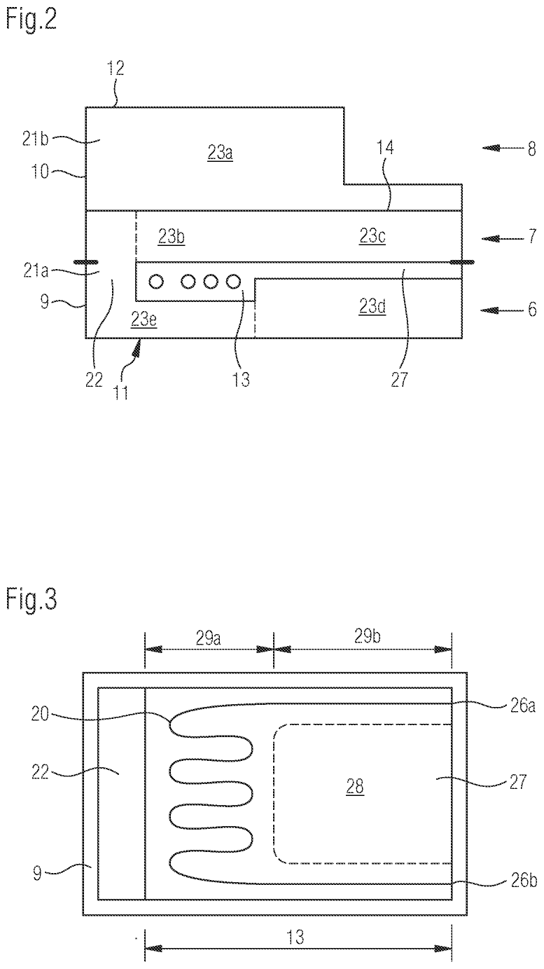

FIG. 2 shows zone division

FIG. 3 shows a sketch of a heat sink with an open-loop control printed circuit board

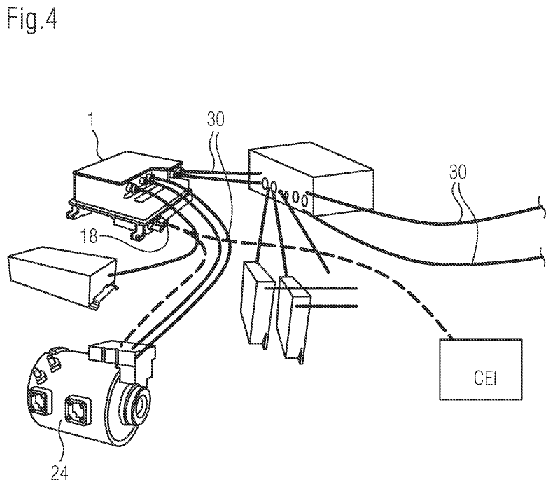

FIG. 4 shows an inverter system in the drive train.

FIG. 1 shows an inverter system 1 in section, so that all of the essential subunits, such as the power converters 5, the drive units (GDUs) 31, the power semiconductors 4, the DC-link capacitors 3 and the open-loop control printed circuit board 2, can be seen.

FIG. 2 shows a sketch of the essential design of the housing with the individual zones 23a to e in which the inverter system 1 is accommodated.

The housing comprising the housing lower part 9, the housing upper part 10, the housing base 11 and the housing lid 12 has three planes 6, 7 and 8 and five essential zones 23a-e within the housing, wherein the housing is sealed off from the surrounding environment. The planes 6 and 7, i.e. the electronics plane 6 and the power plane 7, in this case form a first room 21a. Between the planes 6 and 7 the heat sink 13 is arranged and a passage region 22, for the control power cable 17, is provided.

The third plane 8, the connection plane 8, is a separate room 21b, the zone 23a, within the housing. The room 21b, which forms the zone 23a, is separated off from the room 21a by the separating wall 24 in the housing upper part 10. The necessary control power cable 17 from the power converter 5 to the open-loop control printed circuit board 2 and the conductor bars between the power converter 5 and the power semiconductors 4 are passed through the separating wall 24, wherein sealing elements are provided at the through-openings so that the rooms 21a and b are separated.

The individual zones 23a to e have different functions which are essential for the functionality of the inverter system 1. The connection region 8, zone 23a, is a closed-off region which is accessible very easily by removal of the housing lid so that the connection and disconnection of the terminals of the vehicle-side power cabling can be performed very easily for installation or repair work. Furthermore, the verification of safe isolation from the supply in the DC link can be performed when the housing lid 12 is open.

By virtue of the separating wall 14 not only is a physical separation achieved but also a thermal and EMC-compliant separation with respect to the power region 7, with the result that the power converter 5 and the associated DC contactor are thermally decoupled from the power plane 7 and EMC shielding is ensured.

The room 21a is arranged beneath the connection plane. As can be seen from FIGS. 1 and 2, this room comprises the power region 7 and the electronics region 6, wherein the room 21a is divided into the four zones 23b to e. In the zone 23b, the power semiconductors 4 are positioned on the heat sink 13 so that the waste heat from the power semiconductors 4 can be dissipated efficiently. On the power plane 7, in addition to the power semiconductors 4, the DC-link capacitors 3 are fastened, in zone 23c, on the heat sink 13, which in this zone region is formed substantially by the supply and removal channel 26a, b and a connecting web 27.

The power semiconductors 4 and the DC-link capacitors 3 are connected in terms of power via short conductor bars 16, wherein these conductor bars are accommodated in two different thermal zones 23b and 23c. A thermal zone is understood to mean a region in which defined temperature conditions prevail which differ from other zones or regions.

The heat sink 13 is used as the carrier plane or fastening plane for the power semiconductors 4 and the DC-link capacitors 3. In order to realize the different thermal conditions, the routing of the cooling channels is selected such that the cooling channels run only in the region of the power semiconductors, and the DC-link capacitors 3 are fastened on the web 27 between the supply and removal channel 26a, b. The heat sink 13 therefore has two cooling zones 29a, b.

For the further thermal separation of power semiconductors 4 and DC-link capacitors 3, a thermal interruption is provided which prevents an excessively high level of heat input via the conductor bars 16 from the power semiconductors 4 onto the DC-link capacitors 3. For this purpose, thermally conductive but electrically insulating connections, so-called thermocouples or thermopads 15, are provided between conductor bars 16 and housing upper part 10 which transfer or dissipate at least some of the thermal energy passed on via the conductor bars 16 to the housing as the heat sink.

The open-loop control printed circuit board 2 is arranged in the further zone 23d. It is important for the open-loop control printed circuit board 2 that the room or the zone 23d is shielded from high temperatures and electromagnetic waves, EMC. The zone 23d is located beneath the DC-link capacitors 3. The web 27 of the heat sink 13 is surrounded in this region in the form of a U by the cooling channel in the heat sink 13. Since the web 27 is embodied so as to be relatively thin in comparison with the cooling channel region, a depression 28 results under which the open-loop control printed circuit board 2 is positioned. The shape of the depression, the associated enveloping cubature of the heat sink and the fastening of the open-loop control printed circuit board 2 in the depression 28 can thus be used effectively for the EMC shielding, in particular because the housing 9 with the heat sink 13 consists of an aluminum alloy.

A further zone 23e is a region within the housing through which the control power cables 17 are passed. The control power cables 17 connect the power converters 5 and the drive units (GDUs) 31 to the open-loop control printed circuit board 2 and are laid along the housing wall of the power plane 7 and beneath the heat sink 13 in the electronics plane. Beneath the heat sink 13, the control power cables 17 are partitioned off from the power semiconductor region, the zone 23b, and therefore no additional shielding connections need to be realized or the control power cables 17 of the drive units (GDUs) 31 do not need to be additionally shielded.

FIG. 3 shows a sketch of the housing lower part 9 with the heat sink 13 and the open-loop control printed circuit board 2 fastened thereto. Shown is the depression 28 between the supply and removal channel 26a, b and the web 27 therebetween on which the open-loop control printed circuit board 2 is fastened.

Furthermore, FIG. 4 shows the inverter system 1 in the drive train. This illustration serves for general understanding and shows clearly the separation of the connection planes, how the power plane 8 is connected to the high-voltage cable 30 and how the electronics plane 6 with the control cable connections 18 is connected to the data bus cable.

### LIST OF REFERENCE SYMBOLS

1 inverter system
2 open-loop control printed circuit board
3 DC-link capacitor
4 power semiconductor
5 power converter
6 electronics plane
7 power plane
8 connection plane
9 housing lower part
10 housing upper part
11 housing base
12 housing lid
13 heat sink
14 separating wall
15 thermocouple
16 conductor bars
17 control power cable
18 control cable connection
19 coolant connection
20 cooling channel
21a-b room
22 passage region
23a-e zones
24 motor
25 sealing element
26a, b supply and removal channel
27 web
28 depression
29a, b cooling zones
30 high-voltage cable
31 drive unit (GDU)

1-9. (canceled)

10. An inverter system for a drive train of a motor vehicle, the inverter system comprising:
a multi-part housing;
a plurality of inverter system components disposed in said housing, said components including an open-loop control printed circuit board to be connected to control lines via control cable connections, DC-link capacitors, power semiconductors, drive units, and current converters;
said housing being formed with an electronics plane, a power plane, and a connection plane arranged one above another; and
said housing having an interior with a plurality of zones in which different conditions prevail with respect to at least one of temperature or EMC shielding.

11. The inverter system according to claim 10, further comprising a separating wall separating said housing into a first room and a second room, wherein said power plane 7 and said control plane 6 are arranged in said first room, which in turn is divided into a plurality of zones, and said connection plane is arranged in said second room and forms a zone.

12. The inverter system according to claim 11, which comprises a heat sink disposed in said first room and separating said power plane from said control plane beneath said power plane.

13. The inverter system according to claim 12, wherein said power plane comprises two zones and said control plane comprises two zones, wherein one zone of said power plane and one zone of said control plane adjoin a first cooling zone of said heat sink, and another zone of said power plane and another zone of said control plane adjoin a second cooling zone of said heat sink.

14. The inverter system according to claim 13, wherein in said power plane said power semiconductors are fastened on said heat sink at said first cooling zone and said DC-link capacitors are fastened on said heat sink at said second cooling zone.

15. The inverter system according to claim 13, wherein said open-loop control printed circuit board is arranged in a depression formed in said heat sink in a region of said second cooling zone.

16. The inverter system according to claim 12, which comprises connecting cables coupling said power converters and said open-loop control printed circuit board, said connecting cables running through a zone arranged substantially beneath said heat sink.

17. The inverter system according to claim 10, which comprises conductor bars coupling said power semiconductors and said DC-link capacitors to one another, and wherein said conductor bars are connected via a devices that enable thermal decoupling of said power semiconductors and said DC-link capacitors.

18. The inverter system according to claim 17, wherein said devices are an electrically insulating thermocouple configured to dissipate thermal energy from said conductor bars onto an upper part of said housing.
